(19) United States
(12) Patent Application Publication
(10) Pub. No.: US 2014/0106278 A1
(43) Pub. Date: Apr. 17, 2014

(54) DRY FILM RESIST SHEET AND METHOD OF MANUFACTURING THE SAME

(71) Applicant: SAMSUNG ELECTRO-MECHANICS CO., LTD., Suwon (KR)

(72) Inventors: Hye Jin CHO, Suwon (KR); Suk Jin HAM, Suwon (KR); Sung Hee LIM, Suwon (KR); Kyoung Soon PARK, Suwon (KR)

(73) Assignee: SAMSUNG ELECTRO-MECHANICS CO., LTD., Suwon (KR)

(21) Appl. No.: 13/731,776

(22) Filed: Dec. 31, 2012

(30) Foreign Application Priority Data
Oct. 17, 2012 (KR) 10-2012-0115514

(51) Int. Cl. G03F 7/095

(52) U.S. Cl. CPC G03F 7/0955
USPC 430/283.1; 430/270.1; 430/285.1; 430/286.1; 430/281.1

(57) ABSTRACT

There is provided a dry film resist sheet, including: a base film; a first dry film resist layer formed on the base film, the first dry film resist layer containing a binder polymer, a multi-functional monomer, and a photoinitiator; and a second dry film resist layer formed on the first dry film resist layer, the second dry film resist layer containing a binder polymer, a multi-functional monomer, a photoinitiator, and a thermal initiator.

### CROSS-REFERENCE TO RELATED APPLICATIONS

This application claims the priority of Korean Patent Application No. 10-2012-0115514 filed on Oct. 17, 2012, in the Korean Intellectual Property Office, the disclosure of which is incorporated herein by reference.

### BACKGROUND OF THE INVENTION

1. Field of the Invention

The present invention relates to a dry film resist sheet capable of improving the degree of hardening of a dry film of a printed circuit board, and a method of manufacturing the same.

2. Description of the Related Art

Recently, the trend for multifunctional, high-speed electronic products has progressed rapidly. In order to meet this trend, a heating element such as a semiconductor chip and a printed circuit board having the heating element mounted thereon which connects the heating element to a main substrate have been also developed very rapidly.

This trend is closely associated with higher-speed functions and higher densities in printed circuit boards. In order to implement these features, improvements in and developments of performance have been required, along with printed circuit boards having lighter, thinner, simpler, and smaller structures, finer circuit widths, higher degrees of reliability, and being capable of higher speed signal transmissions.

Meanwhile, a circuit forming process using a dry film resist sheet on the printed circuit board is as follows. A fine circuit is formed in a copper wiring forming process through substrate washing, laminating, exposing, developing, etching, and delaminating. After delaminating, some components of the dry film may leave residue on the surface of copper foil, which may cause defects in processes and products.

Therefore, in the case in which the dry film itself is UV-hardened in the air or in a nitrogen (N) atmosphere, an upper end of the dry film on which a support is present and a lower end of the dry film on which a passivation layer is present have a difference in degrees of hardening thereof, when the difference in degree of hardening according to the thickness of the dry film is measured. In other words, on average, the degree of hardening of a lower portion of the dry film is lower than that of an upper portion of the dry film by approximately 20-30%, which may cause a residue portion to be left on the delaminating end.

Therefore, the present invention is provided to solve this problem of non-hardening in the lower portion of the dry film, and more specifically, improve the degree of hardening of the lower portion of the dry film by reforming the structure of a complex layer composed of two layers of dry films.

### RELATED ART DOCUMENTS

(Patent Document 1) Japanese Patent Laid-Open Publication No. 2007-042395
(Patent Document 2) Japanese Patent Laid-Open Publication No. 2010-160418

### SUMMARY OF THE INVENTION

An aspect of the present invention provides a dry film resist sheet capable of improving the degree of hardening of a dry film of a printed circuit board, and a method of manufacturing the same.

According to an aspect of the present invention, there is provided a dry film resist sheet, including: a base film; a first dry film resist layer formed on the base film, the first dry film resist layer containing a binder polymer, a multi-functional monomer, and a photoinitiator; and a second dry film resist layer formed on the first dry film resist layer, the second dry film resist layer containing a binder polymer, a multi-functional monomer, a photoinitiator, and a thermal initiator.

The dry film resist sheet may further include a protection film formed on the second dry film resist layer.

The protection film may be formed of polyethylene (PE).

The base film may be formed of polyethylene terephthalate (PET).

The binder polymer may be a combination of two or more selected from the group consisting of styrene, methyl methacrylate, acrylic acid, ethyl acrylate, butyl acrylate, and phenoxy diethylene glycol acrylate.

The multi-functional monomer may be selected from the group consisting of polyhydric alcohol, acrylic acid, and methacrylic ester.

The multi-functional monomer may be tetraethyleneglycol diacrylate (TEGDA) or trimethylolpropane triacrylate (TMPTA).

The photoinitiator may be 2-tert-butylanthraquinone (2-TBAQ) or benzophenone (BP).

The thermal initiator may be azobis isobutyronitrile (AIBN).

The thermal initiator may be contained in an amount of 0.05 wt % to 5 wt %, based on the dry film resist sheet.

The first dry film resist layer and the second dry film resist layer may respectively further contain a thermal polymerization inhibitor.

The thermal polymerization inhibitor may be 2-2′-methylene-bis(4-ethyl-6-t-butylphenol).

The first dry film resist layer and the second dry film resist layer may respectively further contain a plasticizer.

The plasticizer may be p-toluenesulfonamide.

The first dry film resist layer and the second dry film resist layer may respectively further contain a photosensitivity enhancer.

The photosensitivity enhancer may be 4,4′-bis(dimethylamino)benzophenone.

According to another aspect of the present invention, there is provided a method of manufacturing a dry film resist sheet, the method including: preparing a base film; forming a first dry film resist layer on the base film, the first dry film resist layer containing a binder polymer, a multi-functional monomer, and a photoinitiator; and forming a second dry film resist layer on the first dry film resist layer, the second dry film resist layer containing a binder polymer, a multi-functional monomer, a photoinitiator, and a thermal initiator.

The method may further include forming a protection film on the second dry film resist layer.

The protection film may be formed of polyethylene (PE).

The base film may be formed of polyethylene terephthalate (PET).

The binder polymer may be a combination of two or more selected from the group consisting of styrene, methyl methacrylate, acrylic acid, ethyl acrylate, butyl acrylate, and phenoxy diethylene glycol acrylate.

The multi-functional monomer may be selected from the group consisting of polyhydric alcohol, acrylic acid, and methacrylic ester.

The multi-functional monomer may be tetraethyleneglycol diacrylate (TEGDA) or trimethylolpropane triacrylate (TMPTA).

The photoinitiator may be 2-tert-butylanthraquinone (2-TBAQ) or benzophenone (BP).

The thermal initiator may be azobis isobutyronitrile (AIBN).

The thermal initiator may be contained in an amount of 0.05 wt % to 5 wt %, based on the dry film resist sheet.

The first dry film resist layer and the second dry film resist layer may respectively further contain a thermal polymerization inhibitor.

The thermal polymerization inhibitor may be 2-2′-methylene-bis(4-ethyl-6-t-butylphenol).

The first dry film resist layer and the second dry film resist layer may respectively further contain a plasticizer.

The plasticizer may be p-toluenesulfonamide.

The first dry film resist layer and the second dry film resist layer may respectively further contain a photosensitivity enhancer.

The photosensitivity enhancer may be 4,4′-bis(dimethylamino)benzophenone.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a dry film resist sheet according to an embodiment of the present invention; and

FIG. 2 is views showing a process for forming the dry film resist sheet according to the embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

Hereinafter, a dry film resist sheet and a method of manufacturing the same, according to an embodiment of the present invention will be described in detail with reference to the accompanying drawings. In the descriptions with reference to the accompanying drawings, the same or corresponding elements are designated by the same reference numerals, and overlapping descriptions thereof will be omitted.

A dry film resist sheet 10 is generally used as a material for forming a fine circuit of a multilayer printed circuit board. The dry film resist sheet 10 is a negative photoresist that induces polymerization by the irradiation of light and has a functional group insoluble in a developing solution.

A light source for a printed circuit board adopts a system in which light polymerization occurs in a wavelength band of 450-300 nm including i-line and g-line. According to the photo-hardening mechanism, polymerization is initiated from a photoinitiator to form a free-radical active intermediate, which then reacts with a monomer to induce chain growth, to thereby form a three-dimensional cross-linkage.

The compositional components contained in the dry film resist sheet 10 are as follows.

A binder polymer is generally used in an amount of 50% or higher, the binder polymer being a matrix resin that determines flexibility, tensile strength, and chemical resistance.

A material that accounts for the next largest proportion of the dry film resist sheet 10 is a monomer, including a double bond. This affects sensitivity, resolution, hardening density, and the like. Since the use of only one kind of monomer makes the exhibition of characteristics difficult, two or more kinds of monomers are generally used. In particular, a multifunctional monomer is used in order to increase cross-linking efficiency.

In addition, as a material for directly generating an active intermediate by irradiation of light, a photoinitiator is used. The photoinitiator generates an active radical at the time of irradiating light, to thereby induce a radical polymerization reaction of the multifunctional monomer having a double bond.

Other additives may be a polymerization promoter, a thermal polymerization inhibitor, an adhesion imparting agent, a photochromic agent, a dye, and a plasticizer, and definitions thereof are as follows.

The polymerization promoter interacts with the photoinitiator, affects sensitivity and the hardening rate, and is effective when a coating film is thin. An aromatic amine is generally and frequently used as the polymerization promoter.

Meanwhile, since a material that induces an initiation reaction by light may induce an initiation reaction by even thermal energy, the thermal polymerization inhibitor is used to prevent polymerization by heat when the dry film resist sheet is produced, kept, transferred, and uncoated, and stabilize characteristics of the dry film resist sheet. The thermal polymerization inhibitor reacts with the generated radical to reduce the reaction rate, thereby inhibiting polymerization.

The adhesion imparting agent is added in order to enhance adhesion with copper foil.

The photochromic agent and the dye cause a color difference in an unexposed portion due to light exposure, thereby facilitating tests and increasing working efficiency.

In addition, the plasticizer serves to impart fluidity at the time of coating and plasticity of a hardening resist.

In the case in which a circuit is formed on a printed circuit board by using the dry film resist sheet 10, when the dry film resist sheet 10 itself is UV-hardened in the air or in a nitrogen (N) atmosphere and then a difference in the degree of hardening according to the thickness of the dry film resist sheet is measured, the difference in the degree of hardening is generated between an upper end of the dry film resist sheet 10 on which a support is present and a lower end of the dry film resist sheet 10 on which a passivation layer is present, which may cause product defects.

According to the measurement principle of the degree of hardening, the degree of hardening is calculated by using the intensity of a C═C bonding peak of acryl before and after hardening with reference to a C═O stretching peak having a low participation degree in the hardening reaction. An equation for calculating the degree of hardening is as follows.

$$\begin{matrix}Hardening \\ Degree\end{matrix} ( \% ) = \{ ( \frac{\begin{matrix}C = C Peak Intensity \\ After Hardening / Before Hardening\end{matrix}}{\begin{matrix}C = O Peak Intensity \\ After Hardening / Before Hardening\end{matrix}} ) \} \times 100$$

As the result of measuring the degree of hardening by the above equation for calculating the degree of hardening, the degree of hardening of the upper portion of the dry film resist sheet 10 may be 80% to 90%, but the degree of hardening of the lower portion of the dry film resist sheet 10 may be 55% to 65%. That is, the degree of hardening of the lower portion of the dry film resist sheet 10 may be lower than the degree of hardening of the upper portion of the dry film resist sheet 10 by an average of 20% to 30%, which may cause the residue portion to be left during a delaminating process.

Therefore, in the embodiment of the present invention, in order to solve the non-hardening problem of the lower portion of the dry film resist sheet 10 and improve the degree of hardening, a predetermined amount of a thermal initiator is added, and two dry film resist layers are formed in the upper and lower portions of the dry film resist sheet 10, respectively.

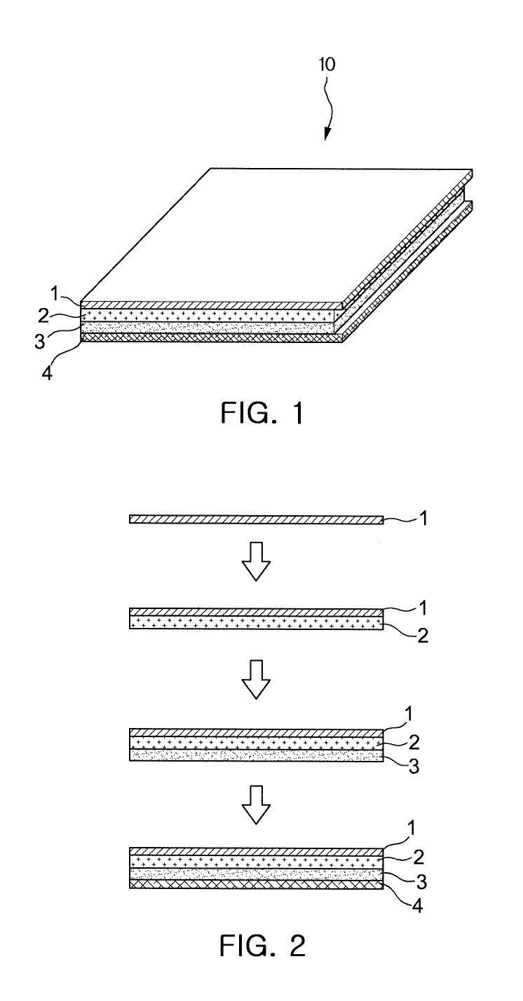

FIG. 1 is a perspective view of the dry film resist sheet 10 according to the embodiment of the present invention.

As shown in FIG. 1, the dry film resist sheet 10 may include a base film 1; a first dry film resist layer 2 formed on the base film 1, the first dry film resist layer 2 containing a binder polymer, a multi-functional monomer, and a photoinitiator; and a second dry film resist layer 3 formed on the first dry film resist layer 2, the second dry film resist layer 3 containing a binder polymer, a multi-functional monomer, a photoinitiator, and a thermal initiator.

Here, the second dry film resist layer 3 positioned below is formed by adding the thermal initiator to the first dry film resist layer 2 positioned above. As the thermal initiator, azobis isobutyronitrile (AIBN), able to induce an initiation reaction, even in the case that a small amount of thermal energy is applied, is preferable. Other thermal initiators may also be used.

FIG. 2 is views showing a process for forming the dry film resist sheet 10 according to the embodiment of the present invention.

As shown in FIG. 2, a method of manufacturing the dry film resist sheet 10 may include: preparing a base film 1; forming a first dry film resist layer 2 on the base film 1, the first dry film resist layer 2 containing a binder polymer, a multi-functional monomer, and a photoinitiator; and forming a second dry film resist layer 3 on the first dry film resist layer 2, the second dry film resist layer 3 containing a binder polymer, a multi-functional monomer, a photoinitiator, and a thermal initiator.

Generally, the dry film resist sheet 10 is formed by coating a photoresist on a support of the base film 1, followed by drying, and then binding a protection film 4 thereto. That is, the dry film resist sheet 10 is formed by casting the first dry film resist layer 2 on the base film 1, followed by drying, and then casting the second dry film resist layer 3 thereon, followed by drying, and then binding the protection film 4 thereto.

In addition, as the result of measuring the degree of hardening of the dry film resist sheet 10 according to the embodiment of the present invention by the above equation for calculating the degree of hardening, the degree of hardening of the upper portion of the dry film resist sheet 10 was 83% and the degree of hardening of the lower portion of the dry film was 81%. That is, in the dry film resist sheet 10 being composed of two layers, the degrees of hardening of the upper and lower portions had approximately the same value, thereby improving the difference in the degree of hardening throughout the dry film resist sheet 10.

As set forth above, according to the embodiments of the present invention, the second dry film resist layer, a lower layer of the dry film resist sheet, is allowed to contain a thermal initiator to thereby improve the degree of hardening of the lower portion of the dry film resist sheet, so that the difference in the degree of hardening can be reduced throughout the dry film resist sheet.

While the present invention has been shown and described in connection with the embodiments disclosed herein, it will be apparent to those skilled in the art that modifications and variations can be made without departing from the spirit and scope of the invention as defined by the appended claims.

What is claimed is:

1. A dry film resist sheet, comprising:
a base film;
a first dry film resist layer formed on the base film, the first dry film resist layer containing a binder polymer, a multi-functional monomer, and a photoinitiator; and
a second dry film resist layer formed on the first dry film resist layer, the second dry film resist layer containing a binder polymer, a multi-functional monomer, a photoinitiator, and a thermal initiator.

2. The dry film resist sheet of claim 1, further comprising a protection film formed on the second dry film resist layer.

3. The dry film resist sheet of claim 2, wherein the protection film is formed of polyethylene (PE).

4. The dry film resist sheet of claim 1, wherein the base film is formed of polyethylene terephthalate (PET).

5. The dry film resist sheet of claim 1, wherein the binder polymer is a combination of two or more selected from the group consisting of styrene, methyl methacrylate, acrylic acid, ethyl acrylate, butyl acrylate, and phenoxy diethylene glycol acrylate.

6. The dry film resist sheet of claim 1, wherein the multi-functional monomer is selected from the group consisting of polyhydric alcohol, acrylic acid, and methacrylic ester.

7. The dry film resist sheet of claim 6, wherein the multi-functional monomer is tetraethyleneglycol diacrylate (TEGDA) or trimethylolpropane triacrylate (TMPTA).

8. The dry film resist sheet of claim 1, wherein the photoinitiator is 2-tert-butylanthraquinone (2-TBAQ) or benzophenone (BP).

9. The dry film resist sheet of claim 1, wherein the thermal initiator is azobis isobutyronitrile (AIBN).

10. The dry film resist sheet of claim 1, wherein the thermal initiator is contained in an amount of 0.05 wt % to 5 wt %, based on the dry film resist sheet.

11. The dry film resist sheet of claim 1, wherein the first dry film resist layer and the second dry film resist layer respectively further contain a thermal polymerization inhibitor.

12. The dry film resist sheet of claim 11, wherein the thermal polymerization inhibitor is 2-2′-methylene-bis(4-ethyl-6-t-butylphenol).

13. The dry film resist sheet of claim 1, wherein the first dry film resist layer and the second dry film resist layer respectively further contain a plasticizer.

14. The dry film resist sheet of claim 13, wherein the plasticizer is p-toluenesulfonamide.

15. The dry film resist sheet of claim 1, wherein the first dry film resist layer and the second dry film resist layer respectively further contain a photosensitivity enhancer.

16. The dry film resist sheet of claim 15, wherein the photosensitivity enhancer is 4,4′-bis(dimethylamino)benzophenone.

17. A method of manufacturing a dry film resist sheet, the method comprising:
preparing a base film;
forming a first dry film resist layer on the base film, the first dry film resist layer containing a binder polymer, a multi-functional monomer, and a photoinitiator; and
forming a second dry film resist layer on the first dry film resist layer, the second dry film resist layer containing a binder polymer, a multi-functional monomer, a photoinitiator, and a thermal initiator.

18. The method of claim 17, further comprising forming a protection film on the second dry film resist layer.

19. The method of claim 18, wherein the protection film is formed of polyethylene (PE).

20. The method of claim 17, wherein the base film is formed of polyethylene terephthalate (PET).

21. The method of claim 17, wherein the binder polymer is a combination of two or more selected from the group consisting of styrene, methyl methacrylate, acrylic acid, ethyl acrylate, butyl acrylate, and phenoxy diethylene glycol acrylate.

22. The method of claim 17, wherein the multi-functional monomer is selected from the group consisting of polyhydric alcohol, acrylic acid, and methacrylic ester.

23. The method of claim 22, wherein the multi-functional monomer is tetraethyleneglycol diacrylate (TEGDA) or trimethylolpropane triacrylate (TMPTA).

24. The method of claim 17, wherein the photoinitiator is 2-tert-butylanthraquinone (2-TBAQ) or benzophenone (BP).

25. The method of claim 17, wherein the thermal initiator is azobis isobutyronitrile (AIBN).

26. The method of claim 17, wherein the thermal initiator is contained in an amount of 0.05 wt % to 5 wt %, based on the dry film resist sheet.

27. The method of claim 17, wherein the first dry film resist layer and the second dry film resist layer respectively further contain a thermal polymerization inhibitor.

28. The method of claim 27, wherein the thermal polymerization inhibitor is 2-2′-methylene-bis(4-ethyl-6-t-butylphenol).

29. The method of claim 17, wherein the first dry film resist layer and the second dry film resist layer respectively further contain a plasticizer.

30. The method of claim 29, wherein the plasticizer is p-toluenesulfonamide.

31. The method of claim 17, wherein the first dry film resist layer and the second dry film resist layer respectively further contain a photosensitivity enhancer.

32. The method of claim 31, wherein the photosensitivity enhancer is 4,4′-bis(dimethylamino)benzophenone.
